(19) United States
(12) Patent Application Publication
(10) Pub. No.: US 2009/0173983 A1
(43) Pub. Date: Jul. 9, 2009

(54) SEMICONDUCTOR DEVICE AND METHOD OF FABRICATING THE SAME

(75) Inventors: Naoki KUSUNOKI, Tokyo (JP); Mutsuo MORIKADO, Kanagawa (JP)

Correspondence Address: FOLEY AND LARDNER LLP;SUITE 500, 3000 K STREET NW, WASHINGTON, DC, 20007, US

(73) Assignee: Kabushiki Kaisha Toshiba

(21) Appl. No.: 12/402,920

(22) Filed: Mar. 12, 2009

Related U.S. Application Data
(63) Continuation of application No. 11/485,278, filed on Jul. 13, 2006.

(30) Foreign Application Priority Data
Jul. 15, 2005 (JP) 2005-207816
Sep. 6, 2005 (JP) 2005-257999

(51) Int. Cl. H01L 29/78

(52) U.S. Cl. 257/314; 257/E29.255

(57) ABSTRACT

A semiconductor device, comprising: a substrate; a floating body region formed in the substrate, a gate electrode formed above a first surface region of the floating body region via a gate insulating film, the gate electrode being connected to a word line; and source and drain regions, respectively, formed on second and third surface regions of the floating body region, the source region being connected to a source line and providing a first electric capacity at an interface relative to the floating body region, the drain region being connected to a bit line and providing a second electric capacity at an interface relative to the floating body region, the second electric capacity being smaller than the first electric capacity.

### CROSS REFERENCE TO RELATED APPLICATIONS

This application is a continuation application of U.S. application Ser. No. 11/485,278, filed Jul. 13, 2006, which is based upon and claims the benefit of priorities from the prior Japanese Patent Application No. 2005-207816 filed on Jul. 15, 2005 and the prior Japanese Patent Application No. 2005-257999 filed on Sep. 6, 2005, the entire contents of all of which are incorporated herein by reference.

### BACKGROUND OF THE INVENTION

The present invention relates to a semiconductor device including FBC (Floating Body Cell) structure, and a method of fabricating the same.

Communication for large capacity data such as moving pictures or the like has increased in accordance with spread of a broadband. In accordance with this situation, LSIs which can process a large amount of data at a high speed have been required. For this reason, a requirement for a technique for simultaneously forming a high-performance microprocessor and a large capacity memory on one semiconductor chip has been increased.

However, a memory cell of a conventional DRAM (Dynamic Random Access Memory) has a structure including one transistor and one capacitor. Hence, there is expected such a problem that the scaling of cell size is to be difficult with the progress of the generation.

As a memory cell for solving the problem, DRAM memory cell referred to as FBC has been developed. A semiconductor device including the FBC structure can perform the memory operation with one transistor, unlike the conventional DRAM. Hence, the semiconductor device has an advantage in which it is suitable for miniaturization in principl. Thus, the semiconductor device including the FBC structure is paid with much attention as a technique for realizing a DRAM embedded system LSI in and after the 45 nm-generation.

A semiconductor device including an FBC structure on a silicon on insulator (SOI) substrate, and a semiconductor device including an FBC structure on a bulk Si have already been reported.

A semiconductor device including an FBC structure on the SOI substrate is described, for example, in Japanese Patent Kokai No. 2003-68877, and a literature of T. Oosawa et al., ISSCC Dig. Tech. Papers, p. 152 (2002), and the semiconductor device including the FBC structure on the SOI substrate is an important device for the purpose of realizing an SOI logic-embedded system LSI.

A semiconductor device including an FBC structure on the bulk Si substrate is described, for example, in a literature of R. Ranica et al., Symp. on VLSI Tech. (2004), and the semiconductor device includes a n-type buried well formed on a p-type Si substrate, a p-type floating well formed on the n-type buried well, source and drain diffusion layers formed in a surface of the p-type floating well, a shallow trench isolation (STI) portion for separating adjacent transistors from each other, and a gate electrode formed via a gate oxide film on the p-type floating well.

This semiconductor device performs a memory operation by accumulating holes in the p-type floating well formed on the n-type buried well.

In the conventional semiconductor device, however, in order to increase a signal amount as a difference between thresholds in cases where “0” and “1” are read out, it is required to increase an impurity concentration of the p-type floating well. When the impurity concentration of the p-type floating well is increased, retention characteristics of a memory is degraded due to an increase in junction leakage current, and a write time is deteriorated due to a deep threshold. For this reason, it is required to realize a semiconductor device in which the signal amount is increased without increasing the impurity concentration of the p-type floating well.

### SUMMARY

According to an embodiment of the invention, a semiconductor device, comprises:

a substrate;

a floating body region formed in the substrate,

a gate electrode formed above a first surface region of the floating body region via a gate insulating film, the gate electrode being connected to a word line; and

source and drain regions, respectively, formed on second and third surface regions of the floating body region, the source region being connected to a source line and providing a first electric capacity at an interface relative to the floating body region, the drain region being connected to a bit line and providing a second electric capacity at an interface relative to the floating body region, the second electric capacity being smaller than the first electric capacity.

According to another embodiment of the invention, a semiconductor device, comprises:

a semiconductor substrate;

a first conductivity type buried well formed in the semiconductor substrate;

a second conductivity type floating body region formed on the first conductivity type buried well;

a gate electrode formed above a first surface region of the second conductivity type floating body region via a gate insulating film;

first conductivity type source and drain regions, respectively, formed on second and third surface regions of the second conductivity type floating body region; and

a structure of increasing an electric capacity formed at an interface between the first conductivity type buried well and the second conductivity type floating body region.

According to still another embodiment of the invention, a method of fabricating a semiconductor device, comprises:

forming a first conductivity type buried well in a semiconductor substrate;

forming a second conductivity type floating body region on the first conductivity type buried well; and

forming a structure of increasing an electric capacity at an interface between the first conductivity type buried well and the second conductivity type floating body region.

### BRIEF DESCRIPTION OF THE DRAWINGS

FIG. 1 is a schematic cross sectional view showing a structure of a semiconductor device according to a first embodiment of the present invention;

FIG. 2A is a schematic plan view showing a memory cell array in which memory cells are arranged in matrix pattern, in the semiconductor device according to the first embodiment of the present invention, and FIG. 2B is a schematic plan view showing a memory cell array in which memory cells are arranged in matrix pattern, in a conventional semiconductor device;

FIG. 3A is a schematic cross sectional view showing an impurity concentration distribution of the semiconductor device according to the first embodiment of the present invention, and FIG. 3B is a schematic cross sectional view showing an impurity concentration distribution of a conventional semiconductor device;

FIG. 4A is a graph showing an operation waveform of a memory cell for which the semiconductor device according to the first embodiment of the present invention is used;

FIGS. 4B to 4G are flow chart diagrams showing steps in operation of a memory cell, for which the semiconductor device according to the first embodiment of the present invention is used;

FIGS. 5A and 5B are graphs showing electric potentials of a floating body region in the semiconductor device according to the first embodiment of the present invention;

FIG. 6 is a graph showing a signal amount relative to a displacement amount of a gate in the semiconductor device according to the first embodiment of the present invention;

FIG. 7 is a graph showing a ratio (C_{db}/C_{sb}) of a capacity (C_{db}) between a drain region and a floating body region to a capacity (C_{sb}) between a source region and the floating body region relative to a signal amount in the semiconductor device according to the first embodiment of the present invention;

FIG. 8 is a schematic plan view showing a memory cell array in which memory cells are disposed in matrix pattern in a modified example of the semiconductor device according to the first embodiment of the present invention;

FIG. 9 is a schematic cross sectional view showing a structure and a fabrication method of a semiconductor device according to a second embodiment of the present invention;

FIG. 10 is a schematic plan view showing a memory cell array in which memory cells are disposed in matrix pattern, in the semiconductor device according to the second embodiment of the present invention;

FIG. 11 is a schematic cross sectional view showing a semiconductor device according to a third embodiment of the present invention;

FIG. 12A is a schematic cross sectional view showing a structure obtained by simulating the semiconductor device according to the third embodiment of the present invention, and FIG. 12B is a schematic cross sectional view showing a structure obtained by simulating a conventional semiconductor device;

FIGS. 13A and 13B are graphs showing V_{g} (gate voltage) relative to I_{d} (drain current) for the semiconductor device according to the third embodiment of the present invention and for the conventional semiconductor device;

FIGS. 14A to 14D are schematic cross sectional views showing a method of fabricating a semiconductor device according to a fourth embodiment of the present invention;

FIG. 15 is a graph showing a P concentration of a semiconductor device fabricated by the method according to the fourth embodiment the present invention;

FIGS. 16A to 16D are schematic cross sectional views showing a method of fabricating a semiconductor device according to a fifth embodiment of the present invention;

FIGS. 17A to 17D are schematic cross sectional views showing a method of fabricating a semiconductor device according to a sixth embodiment of the present invention;

FIG. 18 is a graph showing a B concentration of a semiconductor device fabricated by the method according to the sixth embodiment of the present invention; and

FIGS. 19A, 19B and 19C are schematic cross sectional views showing modifications of the semiconductor device according to the third embodiment of the present invention.

### DETAILED DESCRIPTION

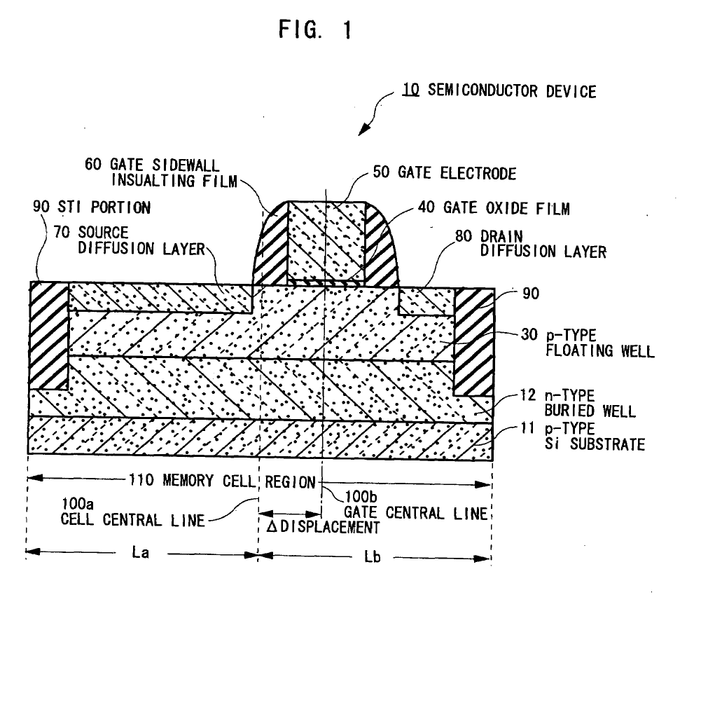

FIG. 1 is a schematic cross sectional view showing a structure, taken in a direction along a bit line, of a semiconductor device according to the first embodiment of the present invention. The semiconductor device 10 is constituted by an n-channel MOS transistor on a Si substrate 11. This MOS transistor includes an n-type buried well 12 which, for example, includes a P concentration of about 1×10¹⁸/cm³ which is formed in the substrate 11, and a p-type floating well 30 which, for example, includes a B concentration of about 3×10¹⁷/cm³ to about 1×10¹⁸/cm³ formed on the n-type buried well 12. The p-type floating well 30 has a floating structure (hereinafter referred to also as simply “body region”) in which the p-type floating well 30 is mutually and electrically insulated from adjacent cells by a shallow trench insulation (STI) portion 90. A gate electrode 50 is formed on the p-type floating well 30 through a gate oxide film 40, and a gate sidewall insulating film 60 is formed on both sidewalls of the gate electrode 50. Moreover, an n⁺-type source diffusion layer 70 and an n⁺-type drain diffusion layer 80 each having an electrically activated P concentration of about 3×10²⁰/cm³ are formed in the p-type floating well 30. Bottom portions of the source diffusion layer 70 and the drain diffusion layer 80 remain within a region of the p-type floating well 30, so that the source diffusion layer 70 and the drain diffusion layer 80 are formed to have a depth not to reach the upper surface of the n-type buried well 12.

Here, the MOS transistor which is held between the adjacent STI portions 90 to include the p-type floating well 30, the gate oxide film 40, the gate electrode 50, the source diffusion layer 70, and the drain diffusion layer 80 is defined as one memory cell region 110 (hereinafter referred to as simply “memory cell”) in the semiconductor device 10.

As shown in FIG. 1, a central line 100b of the gate electrode 50 is located at an asymmetrical position in which it is biased on the side of the drain diffusion layer 80 with respect to a cell central line 100a which is defined in the center of the memory cell region 110. As a result, a distance between the gate electrode 50 and a remote end of the drain diffusion layer 80 is shorter than that between the gate electrode 50 and a remote end of the source diffusion layer 70.

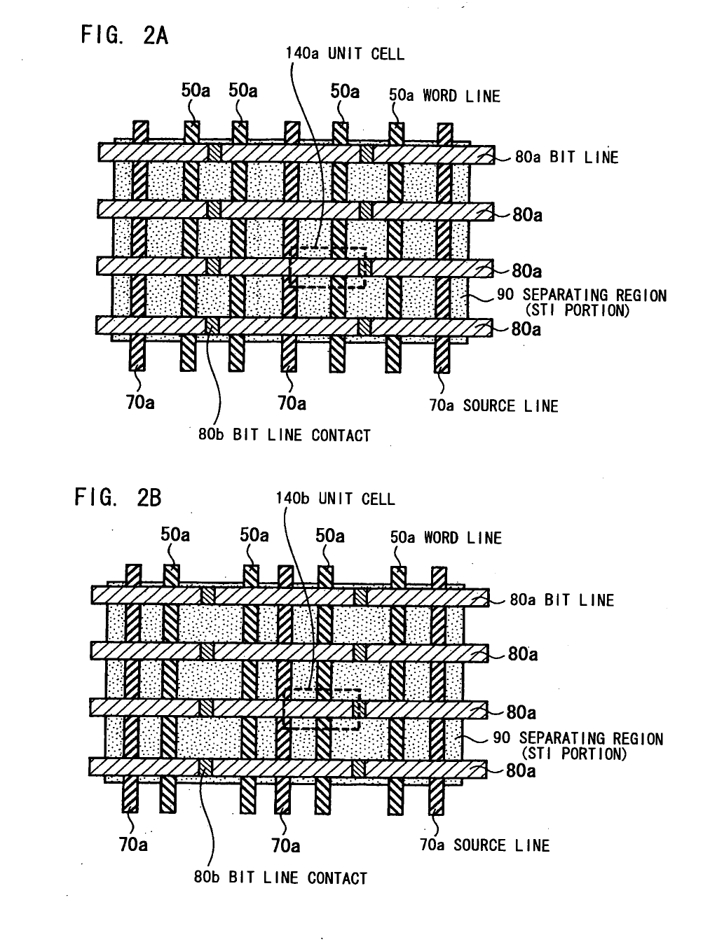

FIG. 2A shows a schematic plan view showing a memory cell array comprising memory cells, which are disposed in matrix pattern, according to the first embodiment of the present invention. When the memory cell array in which the memory cells having FBC structures are disposed in matrix pattern is composed, the gate electrodes 50 are continuously formed in one direction to be word lines 50a, respectively. The source diffusion layers 70 are connected to source lines 70a which are fixed potential lines to which, for example, ground potential is applied, respectively, and continuously formed in the same direction as that of the word lines 50a. Since one source line 70a is in common to the word lines 50a of the adjacent two unit cell 140a, the two unit cell 140a are constituted by one source line 70a per two word lines 50a. One bit line 80a is connected to the drain diffusion layers 80 by a bit line contact 80b in common to the drain diffusion layers 80 of the adjacent two MOS transistors, and the bit lines 80a are continuously formed in a direction of intersecting with the word lines 50a, respectively. The MOS transistor is covered with an interlayer insulating film, through which bit line contacts 80b electrically connected to the drain diffusion layers 80, respectively, are formed. The unit cells 140a for memory cells which are formed in lattice pattern by the word lines 50a, the source lines 70a, and the bit lines 80a are separated from one another by the separating regions 90.

FIG. 2B is a schematic plan view showing a conventional memory cell array in which memory cells each having a gate electrode 50 in the cell central line 100a are disposed in matrix pattern. Comparing the unit cell 140a according to the first embodiment of the present invention with a conventional unit cell 140b, the unit cell 140a of the first embodiment has the same area as that of the conventional unit cell 140b. Here, an area of the unit cell 140a of the first embodiment is not necessary to be the same as that of the unit cell 140b. However, when the structure in which the gate electrode 50 is displaced from the cell central line 100a in a direction on the side of the drain diffusion layer 80 is compared with the structure which is symmetrical with respect to the cell central line 100a, it should be noted that the areas of the respective unit cells 140a and 140b were identical to each other.

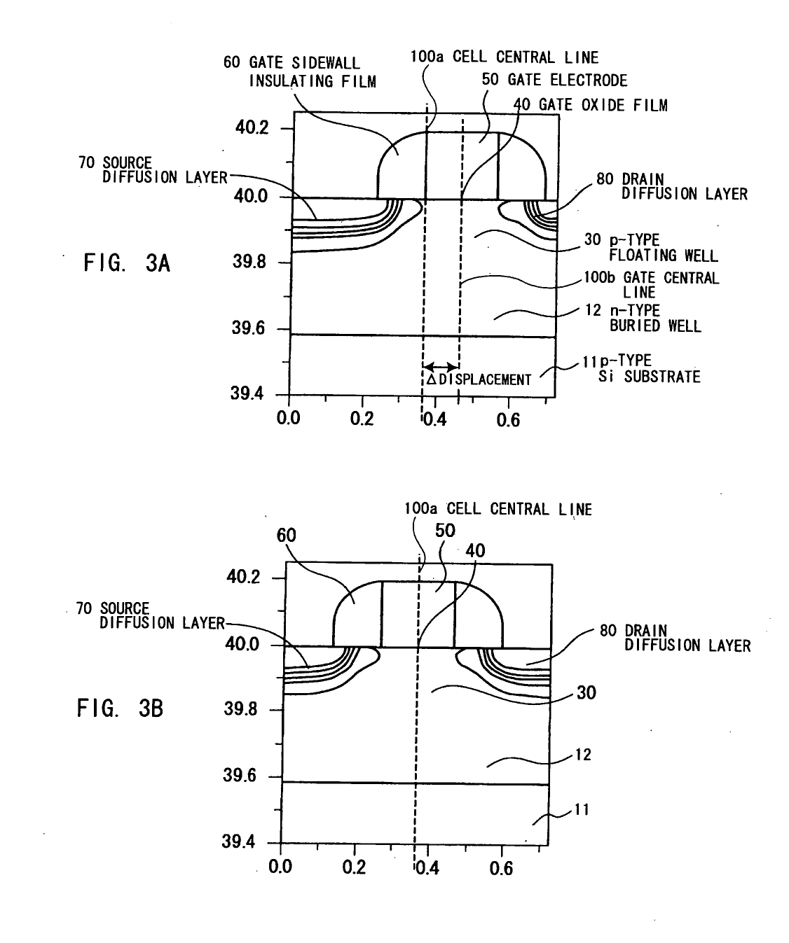

FIG. 3A shows a cross sectional shape of the semiconductor device for a memory cell according to the first embodiment of the present invention, in which, especially, impurity concentration distributions of the source diffusion layer 70 and the drain diffusion layer 80 are shown. The central line 100b of the gate electrode 50 is displaced from the cell central line 100a to the side of the drain diffusion layer 80 by a distance Δ, so that a distance between the center of the gate electrode 50 and the remote end of the source diffusion layer 70 becomes longer than a distance between the center of the gate electrode 50 and the remote end of the drain diffusion layer 80. As a result, it is understood that dosage of the impurity implanted into the drain diffusion layer 80 is smaller than that of the impurity implanted into the source diffusion layer 70, and thus the concentration distribution is asymmetrical with respect to the cell central line 100a. For comparison, FIG. 3B shows the concentration distribution of a memory cell having the conventional structure which is symmetrical with respect to the cell central line 100a.

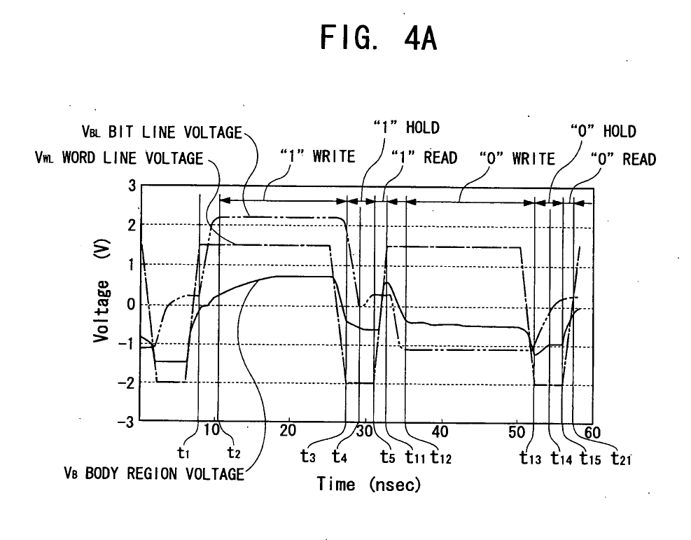

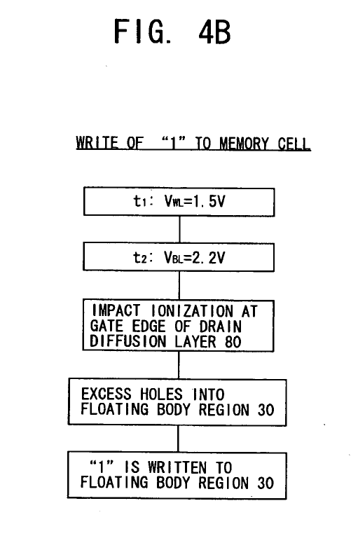

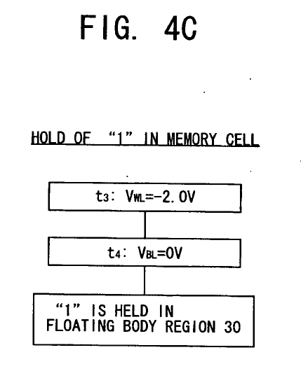

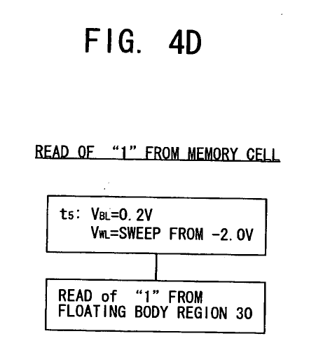

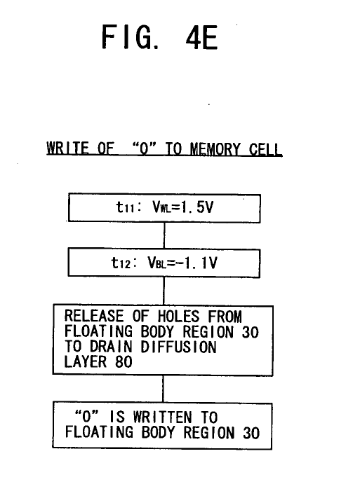

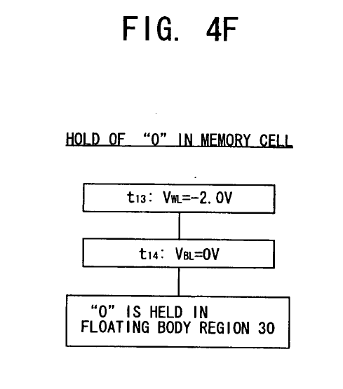

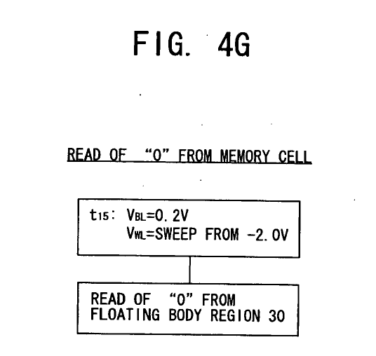

Next, FIG. 4A shows an operation waveform for write, hold and read in a cell selected in the memory cell array in the first embodiment. In addition, TABLE 1 shows a bias condition for a memory operation which is used in calculation in the first embodiment, wherein V_{g} is a gate voltage, V_{d} is a drain voltage, Vₛ is a source voltage, and V_{bn} is a voltage applied to the n-type buried well 12.

TABLE 1
(bias condition)

| | Vg(V) | Vd(V) | Vs(V) | Vbn(V) |
|---|---|---|---|---|
| “1” write | 2.0 | 2.0 | 0.0 | 1.0 |
| “0” write | 2.0 | −1.2 | 0.0 | 1.0 |
| Hold | −2.0 | 0.0 | 0.0 | 1.0 |
| Read | 2.0 | 0.2 | 0.0 | 1.0 |

In FIG. 4A, a bias condition different from that shown in TABLE 1 is used for the sake of making a description easy to understand. Here, concerning a first data state “1” and a second data state “0”, a data state in which holes are injected into the p-type floating well (body region) 30 is defined as “1”, and a data state in which the holes accumulated in the p-type floating well 30 are released is defined as “0”. In the first embodiment, a description will hereinafter be successively given with respect to the case where the selected cell is operated in the order of “1” write→“1” storage and hold→“1” read, and subsequently in the order of “0” write→“0” storage and hold→“0” read. Now, the order of the operation is not limited to this order.

In addition, FIG. 4A shows simultaneously a word line voltage V_{WL}, a bit line voltage V_{BL}, and a body region voltage V_{B}. However, FIG. 4A and TABLE 1 merely show an example of the operating voltage in the first embodiment, and thus there is no necessity of using these voltages. Also, a length of a time axis in the graph shown in FIG. 4A is merely schematically represented, and thus does not limit a relative operating time.

[Write of “1” to Memory Cell (FIG. 4b)]

In order to write “1” to the selected cell, the selected word line voltage V_{WL} of about 1.5 V is applied at a time t₁, and subsequently the selected bit line voltage V_{BL} of about 2.2 V is applied at a time t₂. Thereupon, impact ionization is caused at a gate edge of the drain diffusion layer 80, so that excessive holes are injected and held in the p-type floating well 30, and thus “1” is written thereto.

[Hold of “1” in Memory Cell (FIG. 4c)]

In order to perform the storage and hold of “1” in the selected cell, the selected word line voltage V_{WL} of about −2.0 V is applied at a time t₃, and the selected bit line voltage V_{BL} is set to about 0 V at a time t₄. As a result, “1” is stored and held at the time t₄.

[Read of “1” from Memory Cell (FIG. 4d)]

In order to read “1” from the selected cell, the selected bit line voltage V_{BL} is set to about 0.2 V at a time t₅ while the word line voltage V_{WL} is held at about −2.0 V. Then, the word line voltage V_{WL} is swept from −2.0 V, thereby reading “1” from the selected cell.

[Write of “0” to Memory Cell (FIG. 4e)]

In order to write “0” to the selected cell, the selected word line voltage V_{WL} of about 1.5 V is applied at a time t₁₁, and subsequently the selected bit line voltage V_{BL} is set to about −1.1 V at a at a time t₁₂. Thus, the junction between the p-type floating well 30 and the drain diffusion layer 80 is biased in the forward direction, and thus the holes accumulated in the p-type floating well 30 are released from the selected cell, thereby writing “0”.

[Hold of “0” in Memory Cell (FIG. 4f)]

In order to store and hold “0”, the selected word line voltage V_{WL} of about −2.0 V is applied at a time t₁₃, and the selected bit line voltage V_{BL} is set to about 0 V at a time t₁₄. As a result, “0” is stored and held at the time t₁₄.

[Read of “0” from Memory Cell (FIG. 4g)]

In order to read “0”, the selected bit line voltage V_{BL} of about 0.2 V is applied at a time t₁₅ while the selected word line voltage V_{WL} is held at about −2.0 V, and the word line voltage V_{WL} is swept from −2.0 V, thereby reading “0” from the selected cell. A series of operations from “1” write to “0” read can be performed in the manner described above.

After a time t₂₁ in FIG. 4A, the same operation as described above will be repeated.

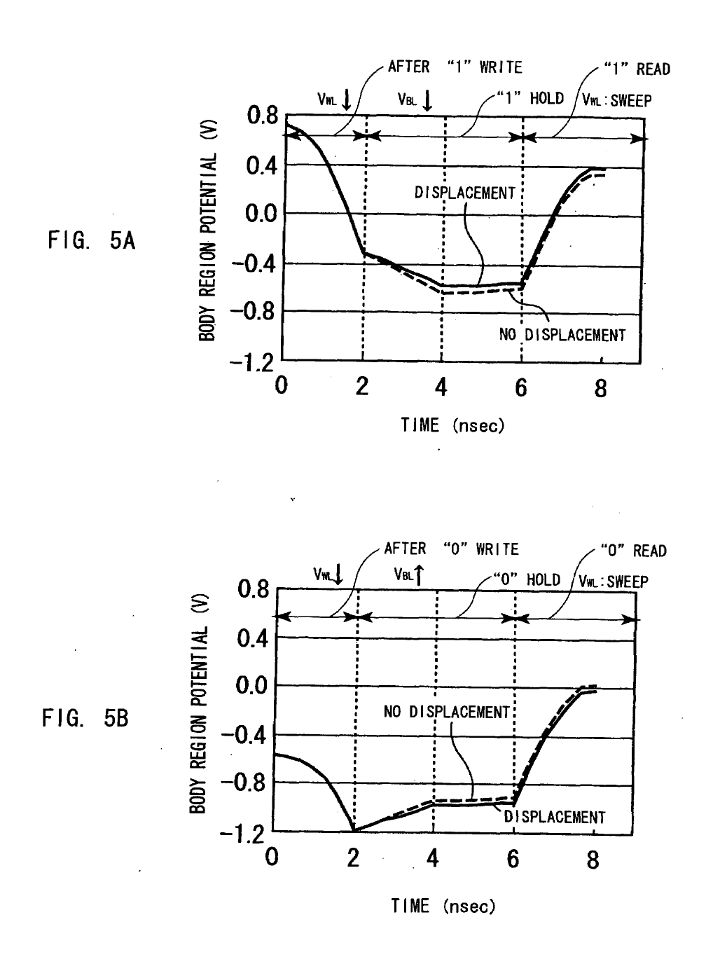

Here, a change amount of a body region voltage V_{B} during the read operation in the selected memory cell of the first embodiment will hereinafter be described in more detail in FIGS. 5A and 5B. FIG. 5A shows the body region voltage V_{B} during the “1” storage and hold and “1” read phases after completion of the “1” write, i.e., the body region voltage V_{B} for a period from the time t₃ to the time t₅ in FIG. 4A. FIG. 5B shows the body region voltage V_{B} during the “0” storage and hold and “0” read phases after completion of the “0” write, i.e., the body region voltage V_{B} for a period from the time t₁₃ to the time t₁₅ in FIG. 4A. Curves indicated by “DISPLACEMENT” in FIGS. 5A and 5B show the body region voltage V_{B} in the case of the asymmetrical structure in which the gate electrode 50 is displaced from the central line 100a to the side of the drain diffusion layer 80 by about 0.05 μm. On the other hand, curves indicated by “NO DISPLACEMENT” in FIGS. 5A and 5B show the body region voltage V_{B} in the case of the comparative conventional symmetrical structure in which the gate electrode 50 is positioned on the cell central line 100a.

Referring to FIG. 5A, a drop of the body region potential V_{B} in the case of “DISPLACEMENT” is further suppressed as composed to that in the case of “NO DISPLACEMENT”. That is to say, the case of “DISPLACEMENT” means that the threshold during the “1” read phase becomes shallow. On the other hand, referring to FIG. 5B, an increase of body region potential V_{B} in the case of “DISPLACEMENT” is suppressed as compared to that in the case of “NO DISPLACEMENT”. That is to say, the case of “DISPLACEMENT” means that the threshold during the “0” read phase becomes deep. As a result, in the case of “DISPLACEMENT”, the threshold during the “1” read phase becomes shallower, and the threshold during the “0” read phase becomes deeper, so that this results in increasing a difference of the thresholds between “1” read and “0” read. That is to say, there is obtained an advantage in which a difference between the two data states becomes large, and the signal amount becomes large.

FIG. 6 shows a relationship between the signal amount relative to a displacement Δ of the central line 100b of the gate electrode 50 from the cell central line 100a to the side of the drain diffusion layer 80. When the central line 100b of the gate electrode 50 coincides with the central line 100a (Δ=0), the signal amount is about 0.19 V. On the other hand, in the case of the displacement Δ of 0.05 μm, the signal amount becomes about 0.25 V. Thus, the signal amount is increased by 0.06 V. This increase means that the signal amount is increased by about 32% by increasing the displacement Δ from 0 to 0.05 μm. Further, when the displacement Δ is 0.1 μm, the signal amount is 0.31 V. As understood from FIG. 6, a displacement Δ of the gate electrode 50 is required to be about 0.02 μm to increase the signal amount by 10%.

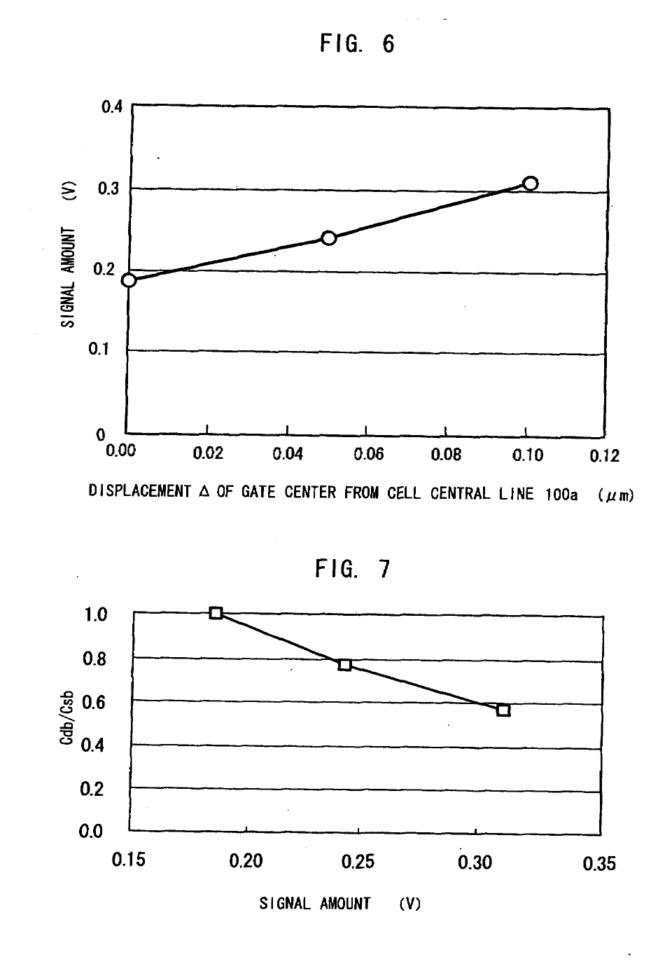

FIG. 7 shows a relation of the signal amount and a ratio (C_{db}/C_{sb}) of a capacity C_{db} between the drain diffusion layer 80 and the body region 30 to a capacity C_{sb} between the source diffusion layer 70 and the body region 30. The signal amount is increased depending on the ratio C_{db}/C_{sb}. For example, it is understood from FIG. 7 that, when the ratio C_{db}/C_{sb} is about 0.93, the signal amount is increased, as compared to the signal amount in case where C_{db}/C_{sb} is 1, by about 10%.

As described above, when the area of the unit cell 140a is set to be a given condition in the first embodiment, the gate electrode 50 is displaced from the cell central line 100a to the side of the drain diffusion layer 80 to provide the structure in which the gate electrode 50, and source and drain diffusion layers 70 and 80 are asymmetrical with respect to the cell central line 100a, i.e., to reduce the ratio C_{db}/C_{sb}, so that it becomes possible to increase the signal amount. In this case, the signal amount can be increased in accordance with the increase in displacement Δ of the central line 100b of the gate electrode 50.

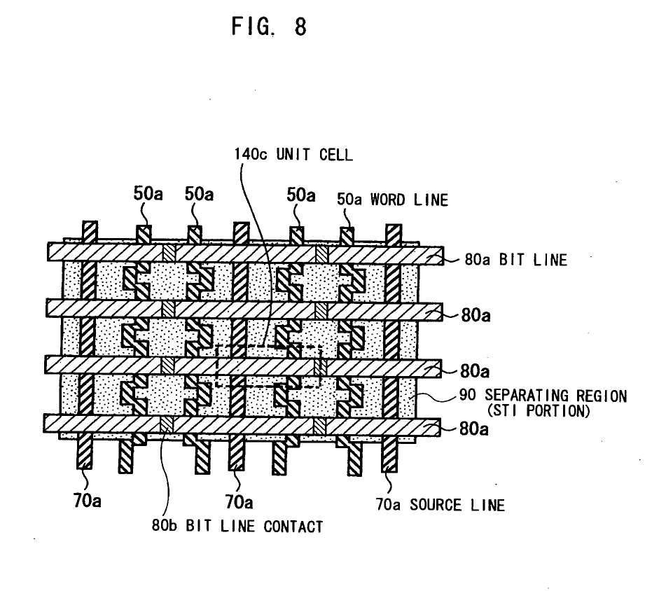

Now, while in the first embodiment, means for shortening the distance between the word line 50a and the remote end of the drain diffusion layer 80 has been described so far by using the word lines 50a each having the straight line structure, any other suitable structure may also be adopted as long as it has the same distance relationship as that in the first embodiment. For example, a structure, having non-straight lines, called a wiggle structure may also be used in a constitution of the word lines 50a. FIG. 8 is an example of a schematic plan view showing a memory cell array using the wiggle structure. Though the structure of the overall memory cell array is the same as that shown in FIG. 2A, its feature is that the word lines 50a are made non-linear. In each region where the word line 50a overlaps the bit line 80a, the word line 50a is close to the drain diffusion layer 80, while in each region where the word line 50a does not overlap the bit line 80a, the word line 50a lies on the cell central line 100a. In addition, the wiggle structure and the straight line structure may be suitably combined with each other.

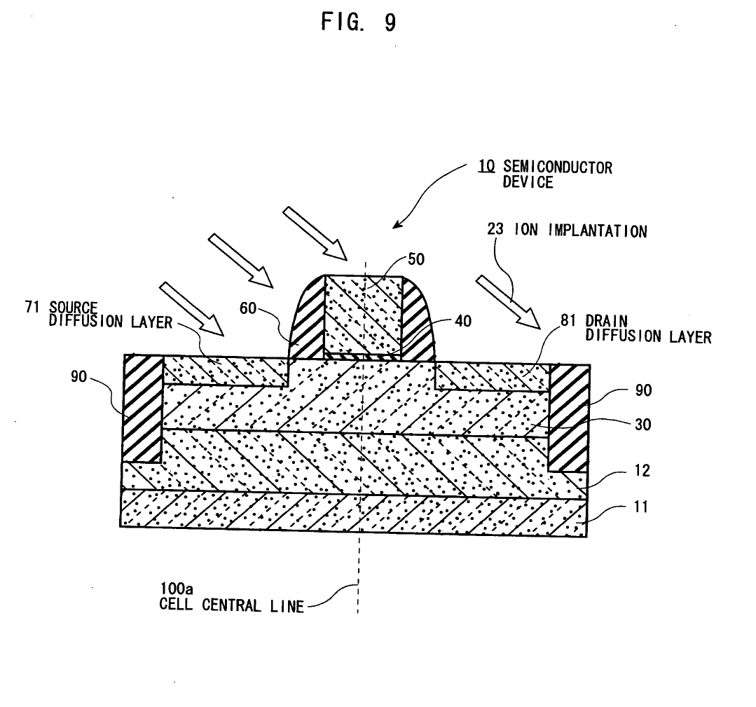

Next, a semiconductor device according to the second embodiment of the present invention will be described with reference to FIGS. 9 and 10.

In the first embodiment, the asymmetrical structure is used in which the central position of the word line is displaced to the side of the drain diffusion layer, thereby reducing the ratio C_{db}/C_{sb}. However, the second embodiment is different from the first embodiment in that impurity concentrations of a drain diffusion layer and a source diffusion layer are made asymmetrical, thereby reducing the ratio C_{db}/C_{sb}.

FIG. 9 is a schematic cross sectional view, taken in a direction along a bit line, of a semiconductor device for a memory cell according to the second embodiment of the present invention. In the second embodiment of the present invention, an impurity concentration of a source diffusion layer 71 is greater than that of a drain diffusion layer 81. As a fabrication method of a semiconductor device having such a structure, an asymmetrical ion implantation method in which, as shown in FIG. 9, implantation 23 of impurity ions is performed at a given angle relative to the substrate 11 during the formation of the source diffusion layer 71 and the drain diffusion layer 81, whereby the impurity concentration of the drain diffusion layer 81 to which a shadow of the gate electrode 50 is cast is intentionally made lighter than that of the source diffusion layer 71 can be, for example, used. Use of this method results in the ratio C_{db}/C_{sb} which can be reduced, and the signal amount which can be increased in correspondence to a change amount of the ratio C_{db}/C_{sb}. That is to say, it is possible to obtain the same effect as that of the first embodiment.

FIG. 10 shows a schematic plan view of a memory cell array according to the second embodiment of the present invention. As can be seen from comparison with the structure shown in FIG. 2A, this memory cell array is structured such that source lines 70a and bit line contacts 80b are disposed on both sides of a word line 50a, wherein one of unit cells is shown by a reference numeral 140c. Other points in structure are the same as those shown in FIG. 2A.

The second embodiment also offers the effect in which the ratio C_{db}/C_{sb} is reduced similarly to the first embodiment. However, the source line 70a and the bit line contact 80b are not common to the source and drain diffusion layers 71 and 81 for adjacent two transistors, so that an area of the unit cell 140c of the second embodiment is different from that of the unit cell 140b, as shown in FIG. 2B, in which the structure is symmetrical with respect to the central line 100a.

Now, though the case where the position of the gate electrode 50 coincides with the cell central line 100a is shown in FIGS. 9 and 10, the gate electrode 50 may be displaced in combination with the displacement method of the first embodiment. Further, the second embodiment may be applied to a semiconductor device fabricated on a SOI substrate.

FIG. 11 is a schematic cross sectional view showing a semiconductor device according to the third embodiment of the present invention. This semiconductor device 10 has an n-type buried well (a buried well of a first conductivity type) 12 formed on a p-type Si substrate 11, and a p-type floating well (a floating body region of a second conductivity type) 13 formed on the n-type buried well 12.

A source diffusion layer 14 and a drain diffusion layer 15 are formed on a surface of the p-type floating well 13, respectively, and a gate electrode 19 is formed on a gate oxide film 17 as a gate insulating film formed on the p-type floating well 13. Also, a gate sidewall insulating film 18 is formed on both sidewalls of the gate electrode 19. A plurality of MOS transistors (only one MOS transistor is illustrated in FIG. 11) each having the above structure are separated from one another by a STI (Shallow Trench Isolation) part 16.

In this MOS transistor, a portion of the p-type floating well 13 is deeper right under the gate electrode 19, and thus a recessed portion 12a is formed at a junction interface between the buried n-type well 12 and the p-type floating well 13. The formation of the recessed portion 12a at the junction interface makes it possible to increase an area of the junction interface.

Here, a width of the recessed portion 12a formed at the junction interface between the n-type buried well 12 and the p-type floating well 13 is preferably made as twice or more as that of a depletion layer from the side of the p-type floating well 13 and a depth thereof is preferably made equal to or larger than the width of the depletion layer from the side of the p-type floating well 13.

Now, though a schematic plan view showing a memory cell array in which memory cells are disposed in matrix pattern in accordance with the third embodiment is omitted herein, the memory cell array may be structured in the same manner, for example, as one which was shown in FIG. 2B. Otherwise, a memory cell array according to the third embodiment may also be structured to provide a smaller ratio of C_{db}/C_{sb} in combination with the first or second embodiment.

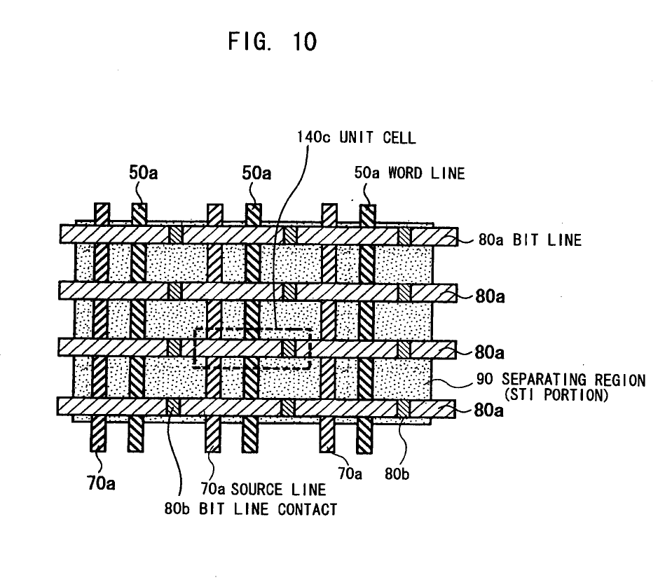

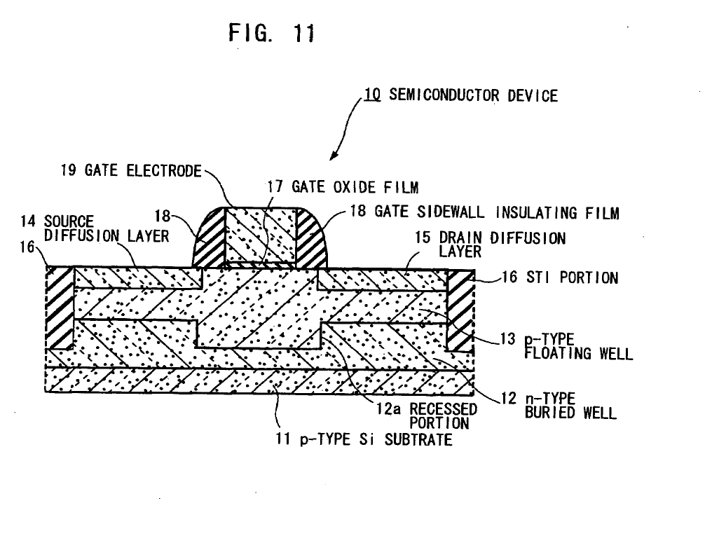

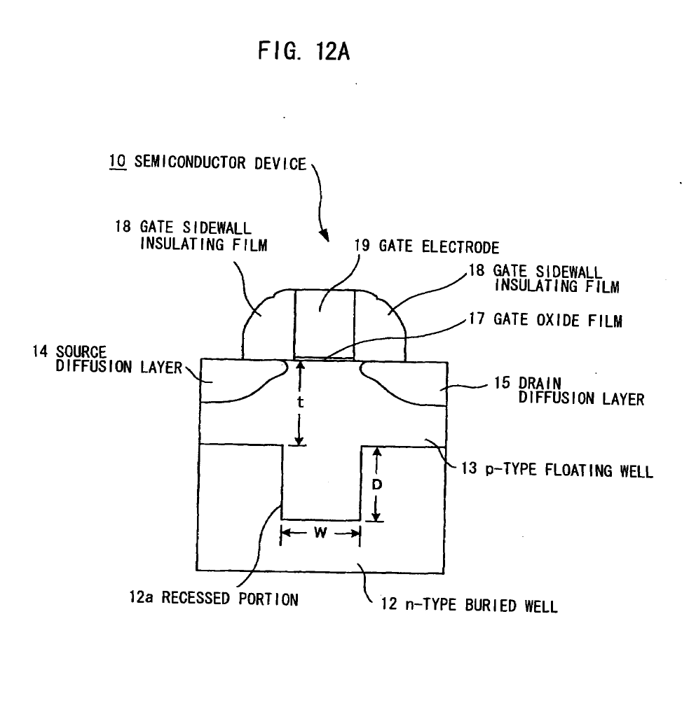

FIG. 12A is a schematic cross sectional view showing results of simulating a cross sectional shape and an impurity distribution of the semiconductor device 10 according to the third embodiment of the present invention, and FIG. 12B is a schematic cross sectional view showing results of simulating a cross sectional shape and an impurity distribution of a comparative conventional semiconductor device 100. As shown in FIG. 12A, since the recessed portion 12a is formed, an area of the junction interface between the n-type buried well 12 and the p-type floating well 13 is increased as compared with that of the comparative conventional semiconductor device 100 shown in FIG. 12B.

In FIG. 12A, a width W of the depletion layer extending to the side of the p-type floating well 13 is 5.8×10⁻² μm. Thus, a width of the recessed portion 12a is preferably made as twice or more as that of the depletion layer, e.g., equal to or larger than 0.12 μm, and a depth D of the recessed portion 12a is made equal to or larger than the width of the depletion layer, e.g., equal to or larger than 0.06 μm. In this simulation, a thickness t of a portion of the p-type floating well 13 in which no recessed portion 12a is formed is 0.25 μm, and both the width W and the depth D of the recessed portion 12a are 0.2 μm. As a result, the area of the junction interface is increased by about 60%.

TABLE 2
(bias condition)

| | Vg(V) | Vd(V) | Vs(V) | Vbn(V) |
|---|---|---|---|---|
| “1” write | 2.0 | 2.0 | 0.0 | 1.0 |
| “0” write | 2.0 | −1.2 | 0.0 | 1.0 |
| Hold | −2.0 | 0.0 | 0.0 | 1.0 |
| Read | 2.0 | 0.2 | 0.0 | 1.0 |

TABLE 2 shows an example of an operation condition of the semiconductor device 10 according to the third embodiment of the present invention. This operation condition is a bias condition during a memory operation. In TABLE 2, V_{g} is a gate voltage, V_{d} is a drain voltage, Vₛ is a source voltage, and V_{bn} is a voltage applied to the n-type buried well 12, wherein they are the same as in TABLE 1.

FIGS. 13A and 13B show results of simulating the operations of the semiconductor devices 10 and 100 shown in FIGS. 12A and 12B, respectively. FIG. 13A shows I_{d} (drain current)−V_{g} (gate voltage) characteristics, when “0” and “1” are read out in the semiconductor device 10 having the structure shown in FIG. 12A. FIG. 13B shows I_{d}−V_{g} characteristics, when “0” and “1” are read out in the conventional semiconductor device 100 having the structure shown in FIG. 12B. Here, I_{d1} indicates a drain current when “1” is read out, and I_{d0} indicates a drain current when “0” is read out.

In the conventional semiconductor device 100, a signal amount SA between a “0” read phase and a “1” read phase is 0.22 V for the gate voltage V_{g} as shown in FIG. 13B. In the semiconductor device 10 according to the third embodiment of the present invention, on the other hand, the signal amount between the “0” read phase and the “1” read phase is 0.34 V for the gate voltage V_{g} as shown in FIG. 13A, and thus increased by about 50% as compared with that in the conventional semiconductor device 100.

It is understood from these results that since in the semiconductor device 10 having the structure shown in FIG. 12A, the junction area between the p-type floating well 13 and the n-type buried well 12 is increased in the presence of the recessed portion 12a, the signal amount SA between the “0” read phase and the “1” read phase is increased for the gate voltage V_{g}.

According to the third embodiment of the present invention, the area of the junction interface between the p-type floating well and the n-type buried well is increased due to the formation of the recessed portion at the junction interface between p-type floating well and the n-type buried well so that a capacity which is required to accumulate the holes is increased. As a result, it is possible to increase the signal amount.

Next, a description will be given with respect to a method of fabricating a semiconductor device according to the fourth embodiment of the present invention.

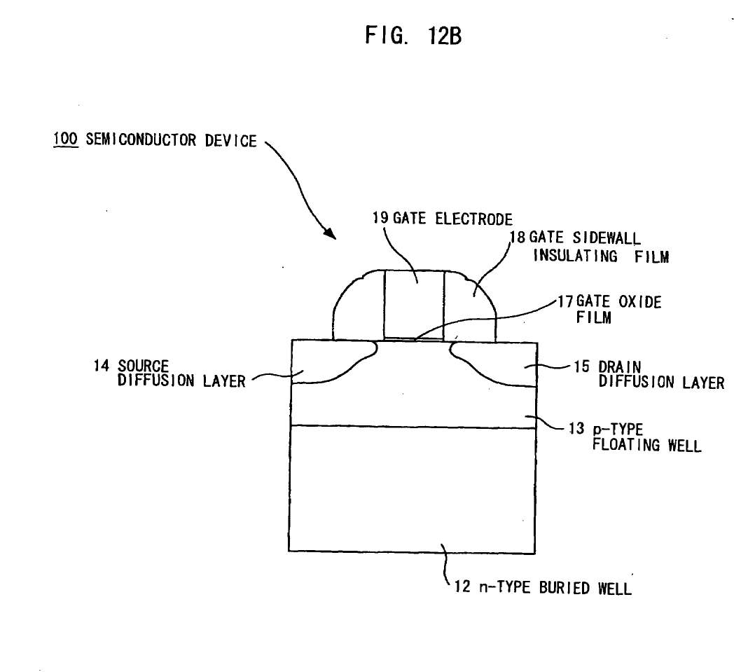

FIGS. 14A to 14D are schematic cross sectional views showing fabrication steps of the method of fabricating a semiconductor device according to the fourth embodiment of the present invention, wherein the same portions as those in FIG. 11 are designated with the same reference numerals, respectively, to omit repeated descriptions thereof.

In FIG. 14A, a STI portion 16 as a cell separation region is formed. Next, ions of an n-type impurity are implanted into the p-type Si substrate 11 to form a layer for an n-type buried well 12. Next, ions of a p-type impurity are implanted on the n-type buried well 12 to form a layer for a p-type floating well 13. Next, anneal is performed to form the n-type buried well 12 and the p-type floating well 13. Next, a thermal oxidation treatment is performed to form a gate oxide film 17.

Here, an example of an ion implantation condition for formation of the n-type buried well 12 and the p-type floating well 13 is as follows.

### (1) N-Type Buried Well 12:

(i) n-type impurity P

(ii) acceleration 480 keV

(iii) dosage 5×10¹³/cm²

(iv) tilt angle 0°

(v) twist angle 0°

### (2) P-Type Floating Well 13:

(i) p-type impurity B

(ii) acceleration 80 keV

(iii) dosage 6×10¹³/cm²

(iv) tilt angle 7°

(v) twist angle 23°

Here, a straight line which extends in parallel with a paper plane and which passes through the p-type floating well 13 in parallel with the junction interface between the p-type floating well 13 and the n-type buried well 12 is defined as x-axis, a straight line which extends in parallel with the paper plane and which passes through the respective centers of the gate electrode 19 and the recessed portion 12a to meet at a right angle with the x-axis at the origin is defined as y-axis, and a straight line which extends perpendicularly to the paper plane and which passes through the origin for an intersection between the x-axis and the y-axis is defined as z-axis. In this case, the tilt angle is an angle between a component, of a straight line indicating the ion implantation direction, on an x-y cross section, and the y-axis, and the twist angle is an angle between a component, of the straight line indicating the ion implantation direction, on an x-z cross section, and the x-axis.

In FIG. 14B, the gate electrode 19 is formed on the gate oxide film 17, a sidewall of the gate electrode 19 is oxidized, and ions of an n-type impurity is implanted into upper portion of the p-type floating well 13 by using the gate electrode 19 as a mask. Then, anneal is performed to form extension regions 14a and 15a for the source and drain diffusion regions. Next, an insulator made of SiN or the like is deposited on the sidewall of the gate electrode 19 to form a gate sidewall insulating film 18.

In FIG. 14C, ion implantation 20 of ions of an n-type impurity is performed by using the gate electrode 19 and the gate sidewall insulating film 18 as a mask. The recessed portion 12a is formed at the junction interface between the n-type buried well 12 and the p-type floating well 13 by this treatment.

Now, a mask such as a photo-resist may be formed on the gate electrode 19 before formation of the recessed portion 12a. As a result, it is possible to prevent the impurity ions from being implanted into a channel region.

Here, an example of an ion implantation condition for formation of the recessed portion 12a is as follows:

(i) n-type impurity P

(ii) acceleration 260 keV

(iii) dosage 1×10¹⁴/cm²

(iv) tilt angle 0°

(v) twist angle 0°

In FIG. 14D, ion implantation of ions of an n-type impurity is performed by using the gate electrode 19 and the gate sidewall insulating film 18 as a mask to form the source diffusion layer 14 and the drain diffusion layer 15. As a result, the semiconductor device 10 is obtained which has been described in the third embodiment of the present invention.

FIG. 15 shows a concentration of P as the n-type impurity relative to a depth from the Si substrate surface (a surface of the p-type floating well 13).

In FIG. 15, a dotted line TOP indicates a depth of 0.25 μm (corresponding to a top portion of the recessed portion 12a) from the Si substrate surface (the surface of the p-type floating well 13), and a dotted line BOTTOM indicates a depth of 0.45 μm (corresponding to a bottom portion of the recessed portion 12a) from the Si substrate surface (the surface of the p-type floating well 13).

It can be understood from FIG. 15 that the concentration of the P ions which are implanted by using the gate electrode 19 and the gate sidewall insulating film 18 as a mask ranges a predetermined concentration in a portion in depth of 0.25 μm to 0.45 μm from the Si substrate surface (the surface of the p-type floating well 13), and thus the recessed portion 12a can be structured in a predetermined shape.

Though the formation of the recessed portion 12a is performed before formation of the source diffusion layer 14 and the drain diffusion layer 15 in the fourth embodiment, the formation of the recessed portion 12a may be performed after formation of the source diffusion layer 14 and the drain diffusion layer 15.

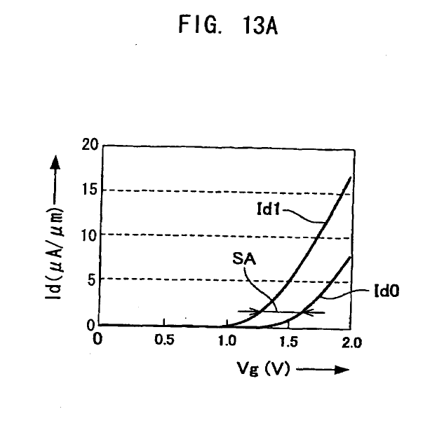

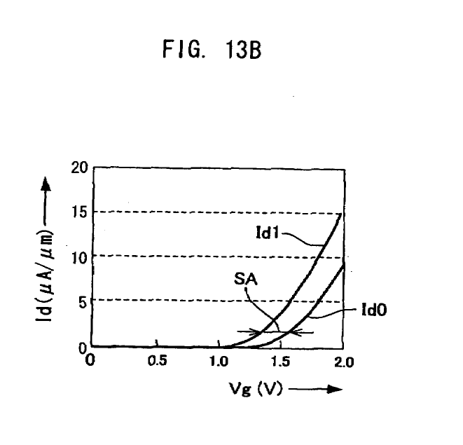

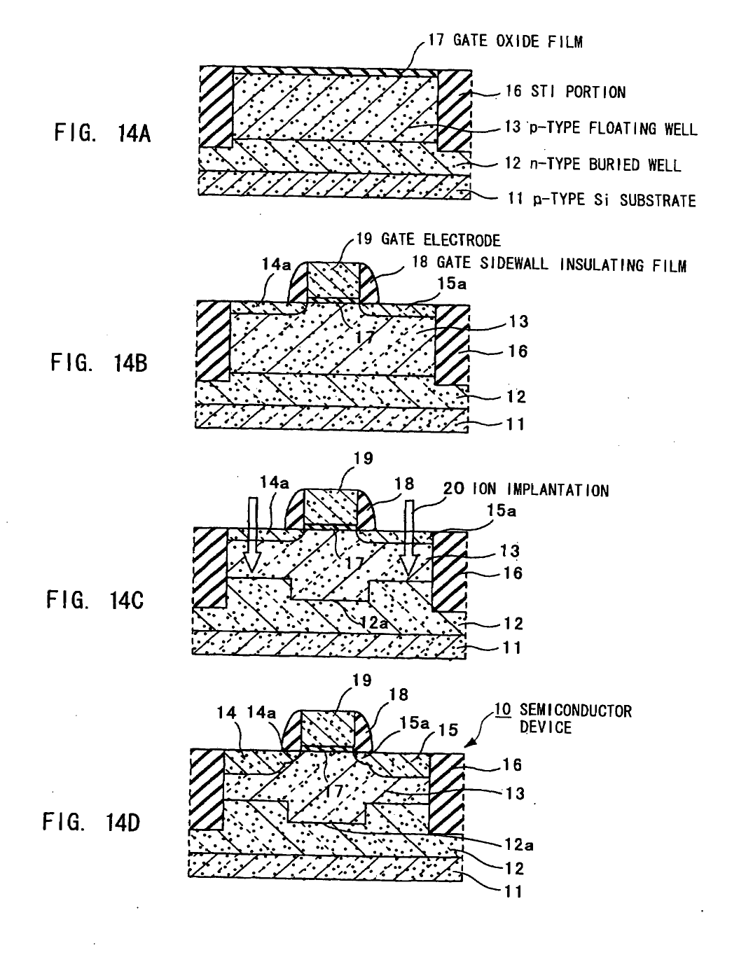

FIGS. 16A to 16D are schematic cross sectional views showing fabrication steps of a method of fabricating a semiconductor device according to a fifth embodiment of the present invention, wherein the same portions as those in FIGS. 14A to 14D are designated with the same reference numerals, respectively, to omit repeated descriptions thereof.

FIG. 16A is common to FIG. 14A. In FIG. 16B, when a height of the gate electrode 19 is low, a hard mask 19a, made of SiN or the like, having a thickness of about 0.5 μm is formed on the gate electrode 19. The hard mask 19a may be replaced with a photo-resist.

In FIG. 16C, ion implantation 20 of P as an n-type impurity is performed under the condition where the hard mask 19a is formed. As a result, the recessed portion 12a is formed at the junction interface between the p-type floating well 13 and the n-type buried well 12.

In FIG. 16D, the hard mask 19a is peeled off, and similarly to the steps shown in FIG. 14D, the ion implantation of the n-type impurity and the anneal are performed to form the source diffusion layer 14 and the drain diffusion layer 15. Now, the formation of the recessed portion 12a may be performed even after formation of the source diffusion layer 14 and the drain diffusion layer 15.

According to the fabrication steps of the fifth embodiment, even when the height of the gate electrode is low, the ions can be prevented from being implanted into the channel region right under the gate oxide film in the ion implantation for increasing the junction area. As a result, it is possible to fabricate a high quality semiconductor device.

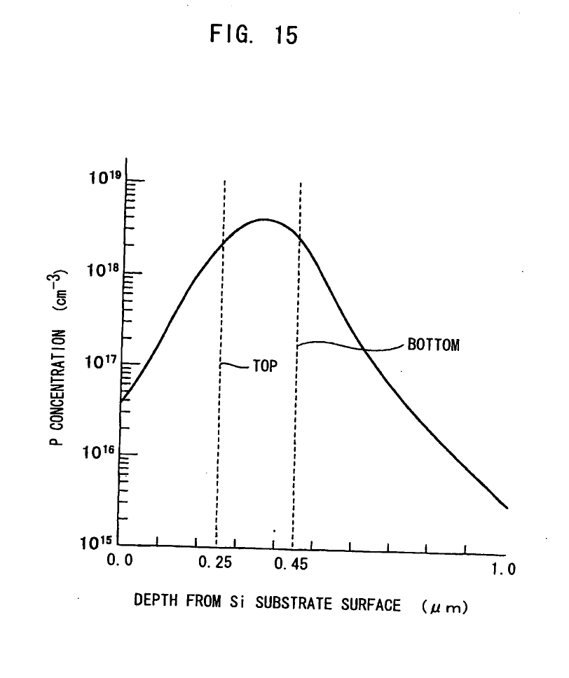

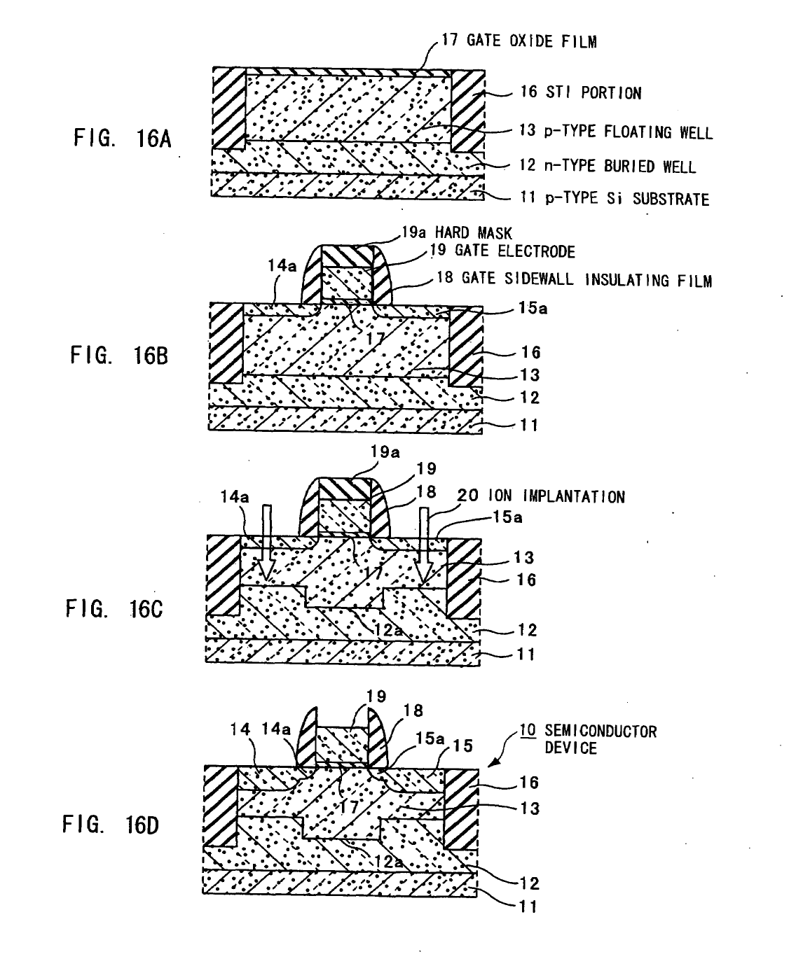

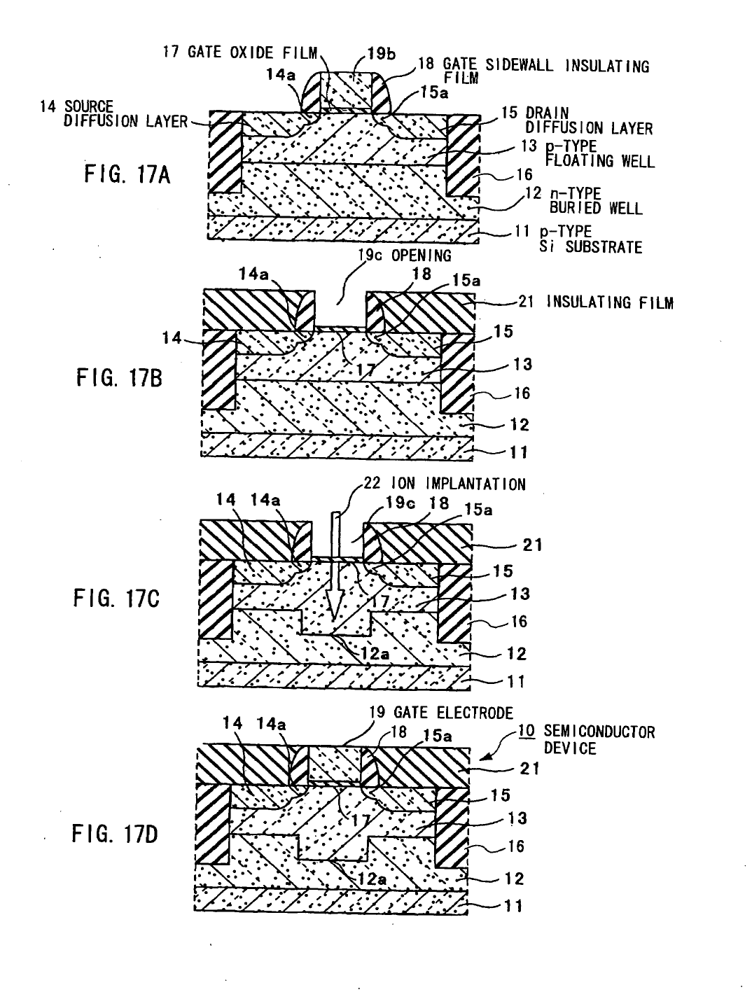

FIGS. 17A to 17D are schematic cross sectional views showing fabrication steps in a method of fabricating a semiconductor device according to a sixth embodiment of the present invention. This method of fabricating a semiconductor device will hereinafter be described.

FIG. 17A shows a structure in which no recessed portion 12a is formed at the pn junction interface and a dummy gate 19b is provided in place of the gate electrode 19, respectively, in the semiconductor device 10 as shown FIG. 14D.

Here, an example of an ion implantation condition for formation of the n-type buried well 12 and the p-type floating well 13 is as follows.

### (1) N-Type Buried Well 12:

(i) n-type impurity P

(ii) acceleration 300 keV

(iii) dosage 5×10¹³/cm²

(iv) tilt angle 0°

(v) twist angle 0°

### (2) P-Type Floating Well 13:

(i) p-type impurity B

(ii) acceleration 50 keV

(iii) dosage 2×10¹³/cm²

(iv) tilt angle 7°

(v) twist angle 23°

In FIG. 17B, an insulating film 21 is deposited, and a surface of the insulating film 21 thus deposited is polished by using chemical mechanical polishing (CMP) until the dummy gate 19b is exposed, so that the insulating film 21 is left around the dummy gate 19b. Next, the dummy gate 19b thus exposed is peeled off to form an opening 19c through the insulating film 21.

In FIG. 17C, ion implantation 22 of B as a p-type impurity is performed through the opening 19c to form the recessed portion 12a at the junction interface between the n-type buried well 12 and the p-type floating well 13.

Here, an example of an ion implantation condition for formation of the recessed portion 12a is as follows:

(i) p-type impurity B

(ii) acceleration 80 keV

(iii) dosage 7×10¹³/cm²

(iv) tilt angle 0°

(v) twist angle 0°

In FIG. 17D, the gate electrode 19 is formed in the opening 19c, thereby completing the semiconductor device 10.

FIG. 18 shows a concentration of B as a p-type impurity relative to a depth from the Si substrate surface of the semiconductor device fabricated through the fabrication steps in the sixth embodiment.

In FIG. 18, a dotted line TOP indicates a depth of 0.25 μm from the Si substrate surface (corresponding to a top portion of the recessed portion 12a), and a dotted line BOTTOM indicates a depth of 0.45 μm from the Si substrate surface (corresponding to a bottom portion of the recessed portion 12a).

It can be understood from FIG. 18 that the concentration of the B ions which are implanted through the opening 19c ranges a predetermined concentration in a portion in depth of 0.25 μm to 0.45 μm from the Si substrate surface, and thus the recessed portion 12a can be structured in a predetermined shape.

According to the fabrication steps in the sixth embodiment, the ion implantation is performed through the opening formed by peeling off the dummy gate, so that the recessed portion can be easily formed at the junction interface between the p-type floating well and the n-type buried well. This results in the increase of the junction area, and thus the capacity required to accumulate the holes can be increased. As a result, it is possible to increase the signal amount during the memory operation.

The following modifications can be made, for example, as explained below.

(1) The conductivity types of the n-type buried well 12, the p-type floating well 13, the source and drain diffusion regions 14 and 15, and the like may be changed to opposite conductivity types, respectively.

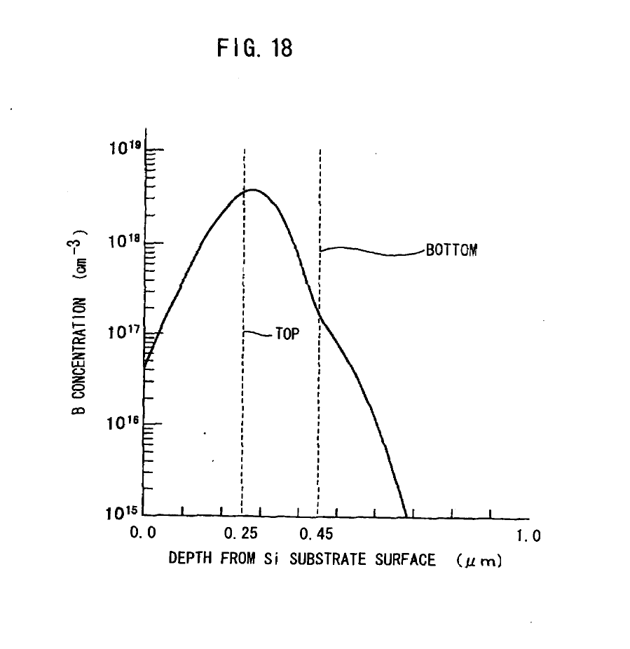

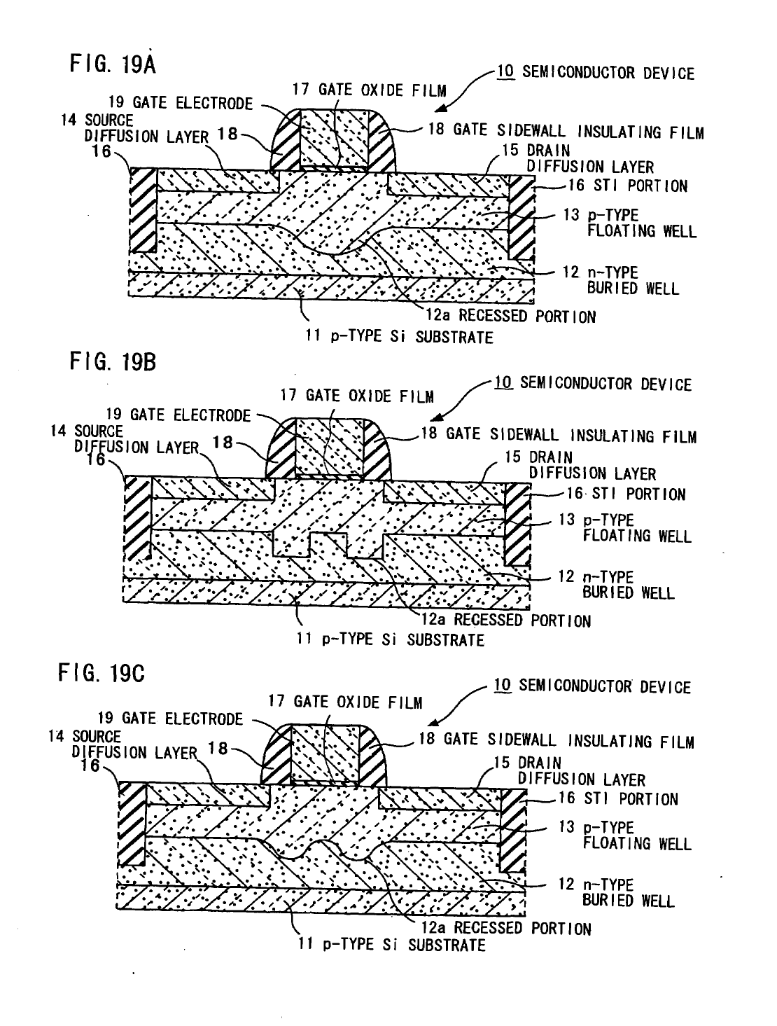

(2) Any other shapes, such as a round recessed shape (FIG. 19A), a substantially right angled concave and convex shape (FIG. 19B) or a round concave and convex shape (FIG. 19C), by which a junction area can be increased may be adopted as a shape of the recessed portion 12a.

(3) Any other elements other than P may also be adopted as an n-type impurity, and any other elements other than B may also be adopted as a p-type impurity.

(4) The recessed portion 12a may be replaced by a projected portion. In such a case, the STI portion 90 may be deeper than a case where the recessed portion 12a is formed.

It should be noted that the present invention is not limited to the above-mentioned embodiments of the present invention, and thus the various modifications can be made without departing from or changing the technical idea of the present invention.

What is claimed is:

1. A semiconductor device, comprising:
a semiconductor substrate;
a first conductivity type buried well formed in the semiconductor substrate;
a second conductivity type floating body region formed on the first conductivity type buried well;
a gate electrode formed above a first surface region of the second conductivity type floating body region via a gate insulating film;
first conductivity type source and drain regions, respectively, formed on second and third surface regions of the second conductivity type floating body region; and
a structure of increasing an electric capacity formed at an interface between the first conductivity type buried well and the second conductivity type floating body region.

2. The semiconductor device, as defined in claim 1, wherein:
the structure includes a recessed portion formed at a junction interface of the first conductivity type buried well relative to the second conductivity type floating body region.

3. The semiconductor device, as defined in claim 2, wherein:
the recessed portion is formed in accordance with the junction interface which is deeper at a portion below the gate electrode than at portions below the first conductivity type source and drain regions.

4. The semiconductor device, as defined in claim 2, wherein:
the recessed portion is of a width as at least twice as a width of a depletion layer from a side of the second conductivity floating body region, and a depth not smaller than the width of the depletion layer therefrom.

5. The semiconductor device, as defined in claim 2, wherein:
the recessed portion is of a substantially right angle at corners.

6. The semiconductor device, as defined in claim 2, wherein:
the recessed portion is of a round shape at corners.

7. The semiconductor device, as defined in claim 2, wherein:
the recessed portion is for a part of a concave and convex shape.

8. The semiconductor device, as defined in claim 2, wherein:
the first conductivity type buried well is formed by ion implantation in a multiple-step process includes a first step and a second step, an implantation depth in the second step being shallower than that in the first step.

9. The semiconductor device, as defined in claim 2, wherein:
the second conductivity type floating body region is formed by ion implantation in a multiple-step process includes a first step and a second step, an implantation depth in the second step being deeper than that in the first step.

10. The semiconductor device, as defined in claim 8, wherein:
a dosage in the second step is higher than that in the first step.

11. The semiconductor device, as defined in claim 9, wherein:
a dosage in the second step is higher than that in the first step.
